(19) United States
(12) Patent Application Publication
(10) Pub. No.: US 2025/0168973 A1
(43) Pub. Date: May 22, 2025

(54) DISPLAY DEVICE AND METHOD OF MANUFACTURING THE SAME

(71) Applicant: Samsung Display Co., LTD., Yongin-si (KR)

(72) Inventors: Cheol Yeong PARK, Yongin-si (KR); Ju Yeop SEONG, Yongin-si (KR); Hee Kwon LEE, Yongin-si (KR); Jae Soo JANG, Yongin-si (KR); Jae Won JEONG, Yongin-si (KR)

(21) Appl. No.: 18/768,602

(22) Filed: Jul. 10, 2024

(30) Foreign Application Priority Data
Nov. 20, 2023 (KR) 10-2023-0161370

(51) Int. Cl. H05K 1/02; H05K 3/28

(52) U.S. Cl. CPC H05K 1/028; H05K 3/28; H05K 2201/10128

(57) ABSTRACT

A display device includes a display panel including a first portion and a second portion bent in one direction from the first portion and disposed to overlap the first portion, a driving integrated circuit (IC) chip disposed on the second portion, and a printed circuit board including a bending unit bent in a direction opposite to the one direction and a wiring unit extending from the bending unit and disposed to overlap the first portion and the second portion.

The application claims priority to Korean Patent Application No. 10-2023-0161370, filed Nov. 20, 2023, and all the benefits accruing therefrom under 35 U.S.C. § 119, the content/s of which in its entirety is herein incorporated by reference.

### BACKGROUND

### (1) Field

Embodiments of the invention relate to a display device and a method of manufacturing the display device.

### (2) Description of the Related Art

In recent years, interest in information display has been increasing. In particular, as the demand for high-quality display devices increases, research and development on display devices are continuously conducted.

A display device including a display panel may include a printed circuit board (PCB), and electronic components inside the display device may be connected to the printed circuit board to receive a power source or to transmit and receive signals.

### SUMMARY

Embodiments of the invention provide a display device with improved ease of design and a method of manufacturing the display device.

An embodiment of the invention relates to a display device. The display device according to embodiments of the invention includes a display panel including a first portion and a second portion bent in one direction from the first portion and disposed to overlap the first portion; a driving integrated circuit (IC) chip disposed on the second portion; and a printed circuit board including a bending unit bent in a direction opposite to the one direction and a wiring unit extending from the bending unit and disposed to overlap the first portion and the second portion.

In an embodiment, the second portion may include an input pad unit, and the printed circuit board may include an output pad unit disposed on the input pad unit and electrically connected to the input pad unit.

In an embodiment, the bending unit may extend from the output pad unit.

In an embodiment, the wiring unit may be adhered to the display panel through adhesive members.

In an embodiment, the adhesive members may include a first adhesive member which adheres the wiring unit to the first portion and a second adhesive member which adheres the wiring unit to the second portion.

In an embodiment, the printed circuit board may further include a protective layer having a predetermined curvature and disposed on the bending unit.

In an embodiment, the protective layer may include a resin.

In an embodiment, the first portion may include a first sub-portion which overlaps the second portion and a second sub-portion which does not overlap the second portion, and the first sub-portion may include a support unit protruding in the one direction.

In an embodiment, the support unit may be spaced apart from the bending unit and may have a shape surrounding the bending unit.

Another embodiment of the invention relates to a method of manufacturing a display device. The method of manufacturing a display device according to embodiments of the invention includes providing a display panel including a first portion and a second portion which is different from the first portion and includes an area where a driving IC chip is disposed; disposing a printed circuit board on an upper surface of the second portion not to overlap the area; bending the printed circuit board in a way such that the printed circuit board is disposed on a rear surface of the second portion; and bending the second portion in a way such that the printed circuit board overlaps the first portion and the second portion.

In an embodiment, the second portion may include an input pad unit, and the printed circuit board may include an output pad unit disposed on the input pad unit and electrically connected to the input pad unit, and a bending unit bent from the output pad unit.

In an embodiment, the printed circuit board may include a wiring unit extending from the bending unit, and the wiring unit may be adhered to the display panel through a first adhesive member and a second adhesive member.

In an embodiment, the wiring unit may be adhered to a rear surface of the second portion through the first adhesive member.

In an embodiment, the wiring unit may be adhered to a rear surface of the first portion through the second adhesive member.

In an embodiment, the method of manufacturing a display device may further include forming a protective layer having a predetermined curvature on the bending unit.

In an embodiment, the protective layer may include resin.

In an embodiment, The first portion may include a first sub-portion which overlaps the second portion and a second sub-portion which does not overlap the second portion, and the first sub-portion may include a support unit protruding in one direction.

In an embodiment, the support unit may be spaced apart from the bending unit and may have a shape surrounding the bending unit.

### BRIEF DESCRIPTION OF THE DRAWINGS

The above and other features of the invention will become more apparent by describing in further detail embodiments thereof with reference to the accompanying drawings, in which:

FIG. 1 is a perspective view of a display panel according to an embodiment of the invention;

FIG. 2 is a plan view of the display panel according to an embodiment of the invention;

FIG. 3 is a perspective view of a display device including the display panel according to an embodiment of FIG. 1;

FIG. 4 is a plan view of the display device including the display panel according to an embodiment of FIG. 2;

FIG. 5 is a flowchart illustrating a method of manufacturing a display device according to an embodiment of the invention;

FIG. 6 is a side view illustrating the display device according to an embodiment of the invention;

FIG. 7 is a side view illustrating a printed circuit board of the display device of FIG. 6 in a bent state;

FIG. 8 is a side view illustrating a display panel of the display device of FIG. 7 in a bent state;

FIG. 9 is a side view of a display device according to an embodiment of the invention; and

FIG. 10 is a side view of a display device according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

Throughout the specification, in a case where a portion is “connected” to another portion, the case includes not only a case where the portion is “directly connected” but also a case where the portion is “indirectly connected” with another element interposed therebetween.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. “At least one of X, Y, and Z” and “at least one selected from X, Y, and Z” may be interpreted as one X, one Y, one Z, or any combination of two or more of X, Y, and Z (for example, XYZ, XYY, YZ, and ZZ). It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in an embodiment, the term “under” may include both directions of on and under. In addition, the device may face in other directions (for example, rotated 90 degrees or in other directions) and thus the spatially relative terms used herein are interpreted according thereto.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

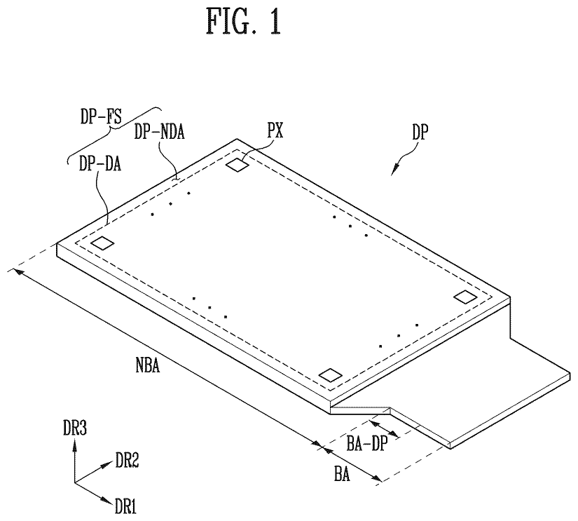

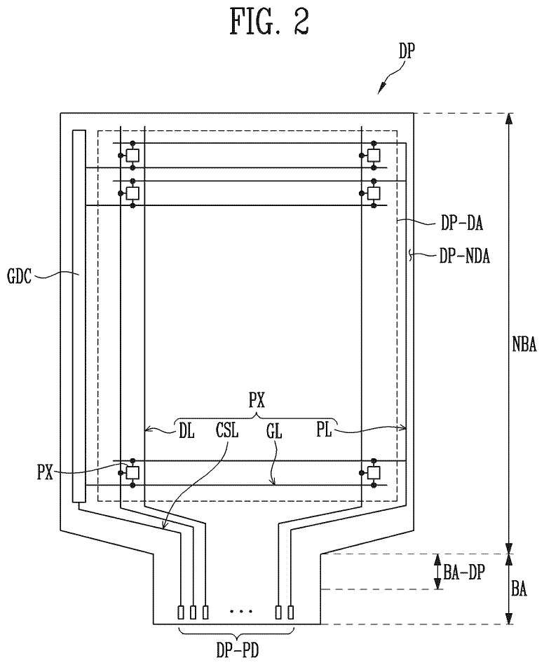

FIG. 1 is a perspective view of a display panel according to an embodiment of the invention. FIG. 2 is a plan view of the display panel according to an embodiment of the invention.

In an embodiment, when a display panel DP is in an unfolded state, a front surface DP-FS of the display panel DP may be parallel to a plane defined by a first direction axis DR1 and a second direction axis DR2. A normal direction of the front surface DP-FS of the display panel DP, that is, a thickness direction of the display panel DP, may be indicated by a third direction axis DR3. An upper surface (or front surface) and a lower surface (or rear surface) of each of layers constituting the display panel DP may be determined or defined based on the third direction axis DR3. Hereinafter, first to third directions may be directions indicated by the first to third direction axes DR1, DR2, and DR3, respectively, and the same reference numerals are used.

Referring to FIG. 1, on the front surface DP-FS, the display panel DP may include a display area DP-DA where pixels PX are disposed and a non-display area DP-NDA adjacent to the display area DP-DA. The non-display area DP-NDA may be an area where the pixels PX are not disposed. Some of signal lines SGL and/or a driving circuit GDC may be disposed in the non-display area DP-NDA.

According to an embodiment, the display area DP-DA may have a square shape. The non-display area DP-NDA may surround the display area DP-DA. However, the invention is not limited thereto, and the shape of the display area DP-DA and the shape of the non-display area DP-NDA may be designed relatively. In an embodiment, for example, non-display areas DD-NDA may be disposed only in areas facing each other in the first direction DR1. The display area DP-DA may have a circular shape.

The display panel DP may be bent. As the display panel DP is bent, the display panel DP may be divided into a first area NBA and a second area BA. In an embodiment, for example, the second area BA of the display panel DP may include a bending area BA-DP, and the bending area BA-DP may be bent in a direction opposite to the third direction DR3. Accordingly, the bending area BA-DP may have a predetermined curvature, and the display panel DP may be divided into the first area NBA and the second area BA.

Referring to FIGS. 1 and 2, an embodiment of the display panel DP may include a driving circuit GDC, a plurality of signal lines SGL, a plurality of input pads DP-PD, and a plurality of pixels PX.

The pixels PX may be divided into a plurality of groups based on the displayed color. The pixels PX may include, for example, red pixels, green pixels, and blue pixels. The pixels PX may further include white pixels. Even if the pixels PX are divided into different groups based on the displayed color, pixel driving circuits of the pixels may be the same as each other.

The driving circuit GDC may include a scan driving circuit. The scan driving circuit may generate a plurality of scan signals and sequentially output the scan signals to a plurality of scan lines GL, which will be described later. The scan driving circuit may further output another control signal to driving circuits of the pixels PX.

The scan driving circuit may include a plurality of thin film transistors formed through a same process as the driving circuits of the pixels PX, for example, a low temperature polycrystalline silicon (LTPS) process or a low temperature polycrystalline oxide (LTPO) process.

The signal lines SGL may include scan lines GL, data lines DL, a power source line PL, and a control signal line CSL. The scan lines GL may be connected to corresponding pixels among the pixels PX, and the data lines DL may be connected to corresponding pixels among the pixels PX. The power source line PL may be connected to the pixels PX. The control signal line CSL may provide control signals to the scan driving circuit. The input pads DP-PD may be connected to corresponding signal lines among the signal lines SGL.

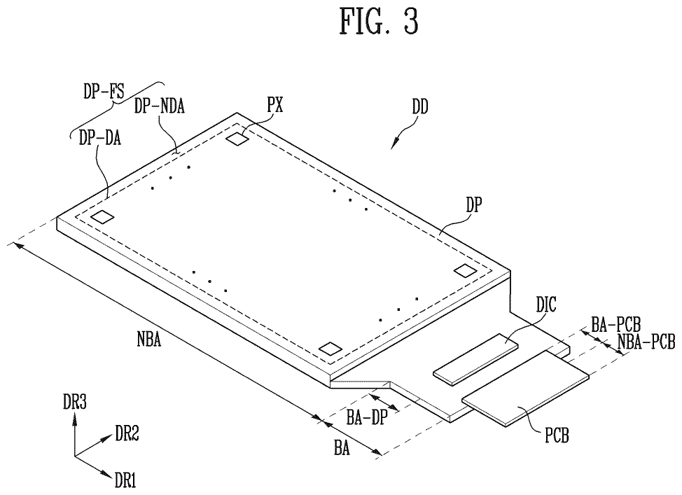

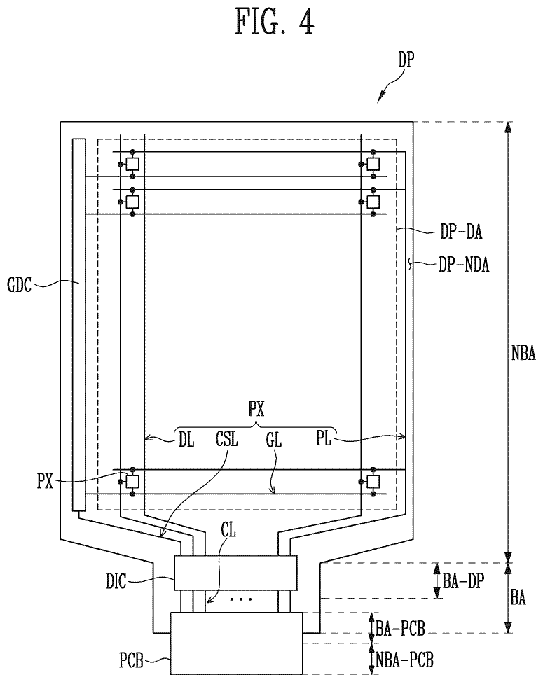

FIG. 3 is a perspective view of a display device including the display panel according to an embodiment of FIG. 1. FIG. 4 is a plan view of the display device including the display panel according to an embodiment of FIG. 2.

Referring to FIGS. 3 and 4, an embodiment of a display device DD may include a display panel DP, a driving integrated circuit (IC) chip DIC, and a printed circuit board PCB. The display panel DP of FIGS. 3 and 4 may be substantially the same as or similarly to the display panel DP of FIGS. 1 and 2. Hereinafter, any repetitive detailed descriptions of the same or like elements as those described above will be omitted.

The display panel DP may include wirings connecting the driving IC chip DIC and the printed circuit board PCB. In an embodiment, for example, the display panel DP may include connection lines CL that transmit and receive electrical signals between the driving IC chip DIC and the printed circuit board PCB.

The driving IC chip DIC may be disposed on the display panel DP. In an embodiment, for example, the driving IC chip DIC may be mounted on the non-display area DP-NDA. According to an embodiment, the driving IC chip DIC may be disposed on the display panel DP using a chip-on glass (COG) method or a chip-on plastic (COP) method.

The driving IC chip DIC may be connected to the signal lines SGL. In an embodiment, for example, the driving IC chip DIC may be connected to the data lines DL and the control signal line CSL.

The printed circuit board PCB may be disposed on the display panel DP. In an embodiment, for example, the printed circuit board PCB may be disposed on the display panel DP to overlap the input pads DP-PD (see FIG. 2). Accordingly, the printed circuit board PCB may be electrically connected to the display panel DP through the input pads DP-PD. In an embodiment, for example, the printed circuit board PCB may be electrically connected to the driving IC chip DIC and the display panel DP via the input pads DP-PD and the connection lines CL.

In this specification, the expression “electrically connected” may include not only a structure in which a first electric component and a second electric component are directly connected, but also a structure in which the first electric component and the second electric component are connected through other electrical components interposed therebetween.

The printed circuit board PCB may be a flexible printed circuit board. Accordingly, the printed circuit board PCB may be bent in a direction opposite to the third direction DR3.

The printed circuit board PCB may include a third area BA-PCB and a fourth area NBA-PCB. In an embodiment, for example, the printed circuit board PCB may include the third area BA-PCB bent in a direction opposite to the third direction DR3. In addition, the printed circuit board PCB may include the fourth area NBA-PCB disposed on the rear surface of the display panel DP as the third area BA-PCB is bent.

The printed circuit board PCB may transmit signals received from the outside. In an embodiment, for example, the printed circuit board PCB may be connected to the display panel DP and the driving IC chip DIC to supply the signals received from the outside.

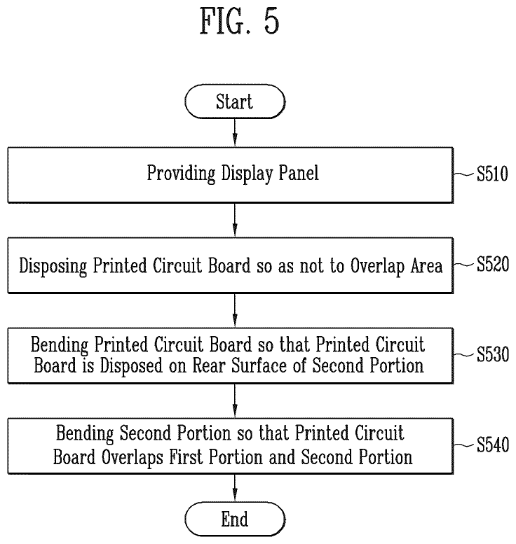

Next, a method of manufacturing a display device according to embodiments of the invention will be described with reference to FIGS. 5 to 8.

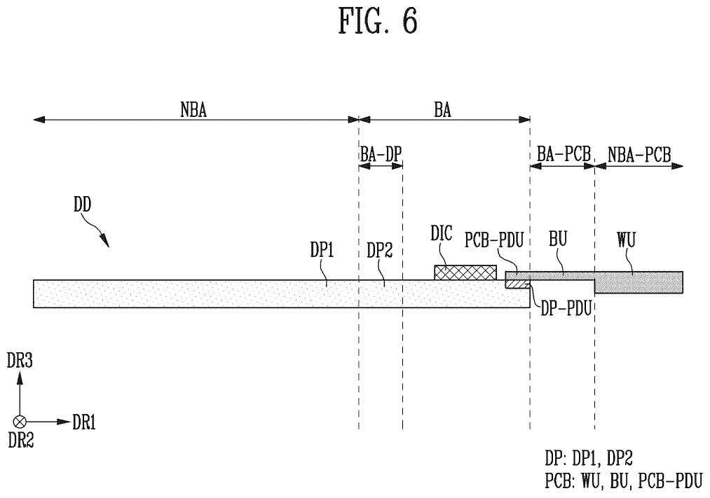

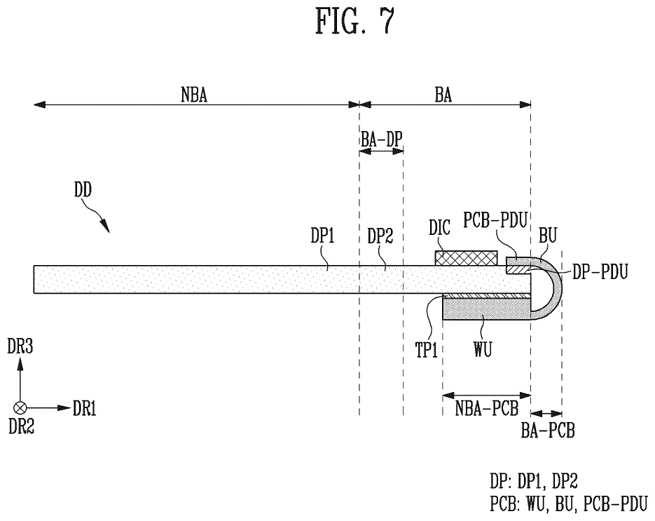

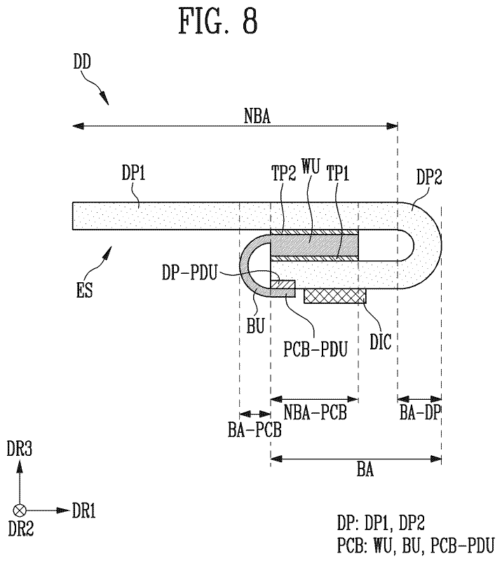

FIG. 5 is a flowchart illustrating a method of manufacturing a display device according to an embodiment of the invention. FIG. 6 is a side view illustrating the display device according to an embodiment of the invention. FIG. 7 is a side view illustrating a printed circuit board of the display device of FIG. 6 in a bent state. FIG. 8 is a side view illustrating a display panel of the display device of FIG. 7 in a bent state.

Referring to FIG. 5, a method of manufacturing a display device according to an embodiment may include providing (or preparing) a display panel (S510), disposing a printed circuit board not to overlap an area (S520), bending the printed circuit board so that (or in a way such that) the printed circuit board is disposed on a rear surface of a second portion (S530), and bending the second portion so that the printed circuit board overlaps a first portion and the second portion (S540).

Referring to FIGS. 1, 5, and 6, in the operation S510, a display panel DP may be provided. In an embodiment, for example, the display panel DP including a first portion DP1 and a second portion DP2 that is different from the first portion DP1 may be provided. The first portion DP1 may be a portion of the display panel DP that overlaps a non-bending area NBA. The second portion DP2 may be a portion of the display panel DP that overlaps a bending area BA and is adjacent to the first portion DP1.

In the operation S510, a driving IC chip DIC may be disposed on the display panel DP. In an embodiment, for example, the driving IC chip DIC may be disposed on an area of the second portion DP2 that overlaps the second area BA.

The display panel DP may include an input pad unit DP-PDU. In an embodiment, for example, the display panel DP may include the input pad unit DP-PDU including the input pads DP-PD (see FIG. 2).

The input pad unit DP-PDU may be disposed on the second portion DP2. In an embodiment, for example, the input pad unit DP-PDU may be disposed on the second portion DP2 not to overlap the driving IC chip DIC. The input pad unit DP-PDU may receive electrical signals from the outside through the input pads DP-PD.

Referring to FIGS. 3, 5, and 6, in the operation S520, a printed circuit board PCB may be disposed not to overlap the area. In an embodiment, for example, the printed circuit board PCB may be disposed s not to overlap the area of an upper surface of the second portion DP2 where the driving IC chip DIC is disposed.

The printed circuit board PCB may include an output pad unit PCB-PDU. In an embodiment, for example, the printed circuit board PCB may include the output pad unit PCB-PDU disposed to overlap the input pad unit DP-PDU. Although not shown, the output pad unit PCB-PDU may include a plurality of output pads. The output pads may be electrically connected to the input pads PD-DU, respectively. Accordingly, the printed circuit board PCB may be electrically connected to the display panel DP and the driving IC chip DIC.

The printed circuit board PCB may include a bending unit BU and a wiring unit WU. In an embodiment, for example, the printed circuit board PCB may include the bending unit BU disposed to overlap a third area BA-PCB and the wiring unit WU disposed to overlap a fourth area NBA-PCB. The bending unit BU may extend from the output pad unit PCB-PDU. The wiring unit WU may include a plurality of wirings. In such an embodiment, the third area BA-PCB and the fourth area NBA-PCB may not overlap the first area NBA and the second area BA.

Referring to FIGS. 6 to 8 together, in the operation S530, a first adhesive member TP1 and a second adhesive member TP2 may be disposed on the printed circuit board PCB. In an embodiment, for example, the first adhesive member TP1 and the second adhesive member TP2 may be disposed on upper and rear surfaces of the wiring unit WU, respectively. Accordingly, the wiring unit WU may be adhered to the first portion DP1 and the second portion DP2.

Referring to FIGS. 5 and 7, in the operation S530, the printed circuit board PCB may be bent so that the printed circuit board PCB is disposed on a rear surface of the second portion DP2. In an embodiment, for example, the third area BA-PCB of the printed circuit board PCB may be bent in a direction opposite to the third direction DR3. Accordingly, the bending unit BU may be bent with a predetermined curvature. In this case, the wiring unit WU of the printed circuit board PCB may be disposed on the rear surface of the second portion DP2. In an embodiment, for example, the fourth area NBA-PCB may be disposed to overlap the second area BA.

According to an embodiment, the printed circuit board PCB may be bent more than two times. In an embodiment, for example, the printed circuit board PCB may include a plurality of bending units, each of the bending units may be bent, and the printed circuit board PCB may be bent two or more times.

In an embodiment, the wiring unit WU may be adhered to the second portion DP2 through an adhesive member. In an embodiment, for example, the first adhesive member TP1 may be disposed on a rear surface of the wiring unit WU. Thereafter, the wiring unit WU may be disposed on the second portion DP2 and the first adhesive member TP1 may be in contact with the rear surface of the second portion DP2. Accordingly, the wiring unit WU may be adhered to the rear surface of the second portion DP2.

Referring to FIGS. 5 and 8, in the operation S540, the second portion DP2 may be bent so that the printed circuit board PCB is disposed to overlap the first portion DP1 and the second portion DP2. In an embodiment, for example, the second portion DP2 may be bent in a direction opposite to the third direction DR3. The wiring unit WU of the printed circuit board PCB may be disposed on a rear surface of the first portion DP1. Accordingly, the risk of electrical interference occurring between the wiring unit WU and the input pad unit DP-PDU can be relatively reduced. In an embodiment, for example, the wiring unit WU may include an electronic circuit disposed to transmit and receive electrical signals. In such an embodiment, the wiring unit WU may be disposed to be spaced apart from the input pad unit DP-PDU in a direction opposite to the third direction DR3 with the second portion DP2 interposed therebetween. Accordingly, the occurrence of electrical interference between electronic circuits included in the wiring unit WU and the input pad unit DP-PDU can be substantially reduced or effectively prevented.

In this operation, the third area BA-PCB may be disposed to overlap the first area NBA. Also, the fourth area NBA-PCB may be disposed to overlap the first area NBA and the second area BA.

In this operation, the wiring unit WU may be adhered to the first portion DP1 through an adhesive member. In an embodiment, for example, the second adhesive member TP2 may be disposed on an upper surface of the wiring unit WU. Thereafter, as the second portion DP2 is bent, the wiring unit WU may be disposed on the first portion DP1 and the second adhesive member TP2 may be in contact with the rear surface of the first portion DP1. Accordingly, the wiring unit WU may be adhered to the rear surface of the first portion DP1.

According to embodiments of the invention, ease of designing the display device DD can be improved. For example, in a case where a plurality of electronic components for driving the display device DD may be disposed on a rear surface of the display panel DP, the display device DD may be desired to provide a component space ES in which the electronic components are disposed on the rear surface of the display panel DP (for example, the rear surface of the first portion DP1).

In a case where the printed circuit board PCB of the display device DD is not bent and only the display panel DP is bent, the printed circuit board PCB may extend in a direction parallel to the second portion DP2 (for example, a direction opposite to the first direction DR1). Accordingly, the first portion DP1 and the second portion DP2 may be spaced apart from each other in the third direction DR3, so that an empty space may exist between the first portion DP1 and the second portion DP2. Accordingly, a filling member may be desired to be provided to fill the space between the first portion DP1 and the second portion DP2. In addition, the component space ES disposed on the rear surface of the first portion DP1 may be relatively reduced, and the ease of designing the display device DD may be reduced.

In embodiments of the invention, as described above, the bending unit BU of the printed circuit board PCB is bent and the wiring unit WU is disposed between the first portion DP1 and the second portion DP2, such that the printed circuit board PCB may be disposed on the rear surface of the display panel DP, and the space occupied by the printed circuit board PCB may be relatively reduced. Accordingly, the component space ES can be relatively increased, and the display device DD can be manufactured so that the thickness (for example, the height in the third direction DR3) of the display device DD is relatively thin. In addition, according to embodiments of the invention, by disposing the wiring unit WU between the first portion DP1 and the second portion DP2, the display device DD can be manufactured without disposing the filling member between the first portion DP1 and the second portion DP2. Accordingly, the ease of designing the display device DD can be improved.

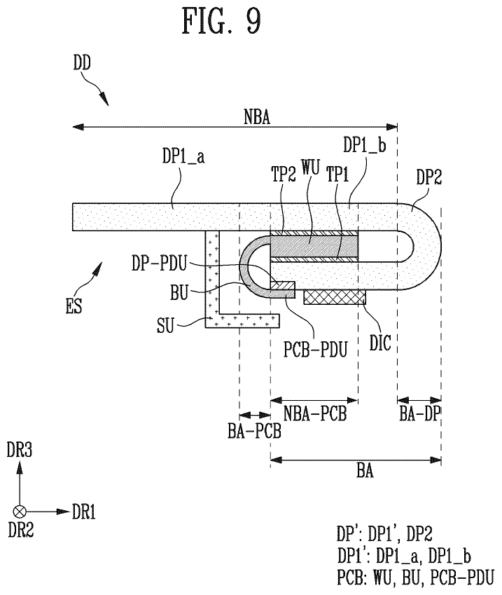

FIG. 9 is a side view of a display device according to an embodiment of the invention.

Referring to FIG. 9, an embodiment of a display panel DP′ may include a first portion DP1′ and a second portion DP2. A printed circuit board PCB may include an output pad unit PCB-PDU, a bending unit BU, and a wiring unit WU.

The printed circuit board PCB of FIG. 9 may be substantially the same as the printed circuit board PCB of FIG. 8 except for a support unit SU, and any repetitive detailed descriptions of the same or like elements as those described above will be omitted.

In an embodiment, the first portion DP1′ may include a first sub-portion DP1_a and a second sub-portion DP1_b that is different from the first sub-portion DP1_a.

The first sub-portion DP1_a may be a portion extending in the first direction DR1 to a portion where the first portion DP1′ overlaps an end portion of the bending portion BU that protrudes most in one direction (for example, a direction opposite to the first direction DR1). The first sub-portion DP1_a may overlap a non-bending area NBA.

The second sub-portion DP1_b may be disposed between the first sub-portion DP1_a and the second portion DP2. The second sub-portion DP1_b may overlap a third area BA-PCB and a fourth area NBA-PCB.

The first sub-portion DP1_a may include the support unit SU protruding in one direction. The support unit SU may protrude in a direction opposite to the third direction DR3 on a rear surface of the first sub-portion DP1_a.

The support unit SU may be disposed to be spaced apart from the bending unit BU by a predetermined distance. In addition, the support unit SU may have a shape that surrounds the bending unit BU. In an embodiment, for example, the support unit SU may have a shape that surrounds the bending unit BU having a predetermined curvature in the first direction DR1 and/or the third direction DR3. According to an embodiment, the support unit SU may have an ‘L’ shape, may be spaced apart from the bending unit BU, and may cover the bending unit BU. However, this is only an example, and the shape of the support unit SU is not limited as long as it can protect the printed circuit board PCB from external shock.

According to an embodiment of the invention, the support unit SU may protect the printed circuit board PCB from external shock. For example, as described above, a plurality of electronic components may be disposed in a component space ES, and corresponding electronic components may impact the printed circuit board PCB (for example, the bending unit BU or the output pad unit PCB-PD) in the first direction DR1 and/or the third direction DR3. In such an embodiment, the support unit SU may effectively prevent the printed circuit board PCB from colliding with the electronic components and may effectively prevent shock from being applied to the printed circuit board PCB.

Referring to FIGS. 5, 8, and 9 together, after bending the second portion DP2 so that the printed circuit board PCB overlaps the first portion DP1′ and the second portion DP2, the support unit SU nay be disposed on the first sub-portion DP1_a. According to some embodiments, the method of manufacturing a display device according to embodiments of the invention may further include curing the support unit SU.

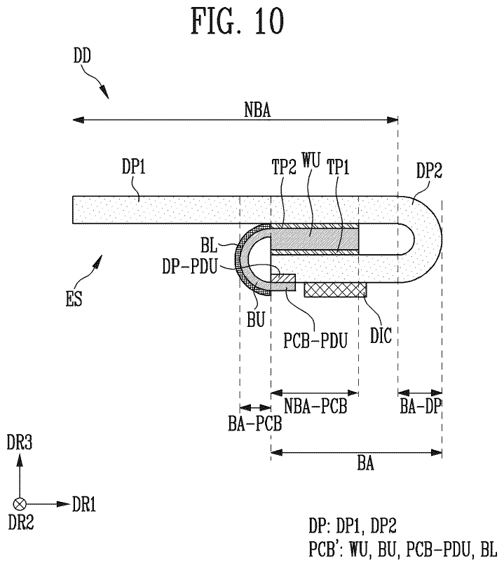

FIG. 10 is a side view of a display device according to an embodiment of the invention.

Referring to FIG. 10, an embodiment of a display panel DP may include a first portion DP1 and a second portion DP2. A printed circuit board PCB′ may include an output pad unit PCB-PDU, a bending unit BU, a wiring unit WU, and a protective layer BL.

The display panel DP of FIG. 10 may be substantially the same as the display panel DP of FIG. 8 except for the protective layer BL, and any repetitive detailed descriptions of the same or like elements as those described above will be omitted.

In an embodiment, as shown in FIG. 10, the protective layer BL may be formed on the bending unit BU. In an embodiment, for example, the protective layer BL may be formed by applying materials forming the protective layer BL onto the bending unit BU having a predetermined curvature. According to an embodiment, the protective layer BL may include resin.

The protective layer BL may be a bending protective layer. In an embodiment, for example, the protective layer BL may be formed by applying a material containing silicon on the bending unit BU several times.

Referring to FIGS. 5, 8, and 10 together, after bending the second portion DP2 so that the printed circuit board PCB overlaps the first portion DP1 and the second portion DP2, the protective layer BL may be formed on the bending unit BU. According to some embodiments, the method of manufacturing a display device according to embodiments of the invention may further include curing the protective layer BL.

According to embodiments of the invention, the protective layer BL may protect the printed circuit board PCB from external shock. In an embodiment, for example, the bending unit BU is entirely covered by the protective layer BL, such that the bending unit BU can be protected from impact caused by electronic components in the first direction DR1 and/or the third direction DR3. Accordingly, the protective layer BL may minimize or at least reduce impact transmitted from the bending unit BU to the wiring unit WU and/or the output pad unit PCB-PDU.

According to embodiments of the invention, a display device with improved ease of design and a method of manufacturing the a display device may be provided.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

1. A display device comprising:
a display panel including a first portion and a second portion bent in one direction from the first portion and disposed to overlap the first portion;
a driving integrated circuit chip disposed on the second portion; and
a printed circuit board including a bending unit bent in a direction opposite to the one direction and a wiring unit extending from the bending unit and disposed to overlap the first portion and the second portion.

2. The display device of claim 1, wherein the second portion includes an input pad unit, and
wherein the printed circuit board includes an output pad unit disposed on the input pad unit and electrically connected to the input pad unit.

3. The display device of claim 2, wherein the bending unit extends from the output pad unit.

4. The display device of claim 3, wherein the wiring unit is adhered to the display panel through adhesive members.

5. The display device of claim 4, wherein the adhesive members include a first adhesive member which adheres the wiring unit to the first portion and a second adhesive member which adheres the wiring unit to the second portion.

6. The display device of claim 2, wherein the printed circuit board further includes a protective layer having a predetermined curvature and disposed on the bending unit.

7. The display device of claim 6, wherein the protective layer includes a resin.

8. The display device of claim 2, wherein the first portion includes a first sub-portion which overlaps the second portion and a second sub-portion which does not overlap the second portion, and
wherein the first sub-portion includes a support unit protruding in the one direction.

9. The display device of claim 8, wherein the support unit is spaced apart from the bending unit and has a shape surrounding the bending unit.

10. A method of manufacturing a display device, the method comprising:
providing a display panel including a first portion and a second portion which is different from the first portion and includes an area where a driving integrated circuit chip is disposed;
disposing a printed circuit board on an upper surface of the second portion not to overlap the area;
bending the printed circuit board in a way such that the printed circuit board is disposed on a rear surface of the second portion; and
bending the second portion in a way such that the printed circuit board overlaps the first portion and the second portion.

11. The method of claim 10, wherein the second portion includes an input pad unit, and
wherein the printed circuit board include an output pad unit disposed on the input pad unit and electrically connected to the input pad unit, and a bending unit bent from the output pad unit.

12. The method of claim 11, wherein the printed circuit board includes a wiring unit extending from the bending unit, and
wherein the wiring unit is adhered to the display panel through a first adhesive member and a second adhesive member.

13. The method of claim 12, wherein the wiring unit is adhered to a rear surface of the second portion through the first adhesive member.

14. The method of claim 12, wherein the wiring unit is adhered to a rear surface of the first portion through the second adhesive member.

15. The method of claim 11, further comprising:
forming a protective layer having a predetermined curvature on the bending unit.

16. The method of claim 15, wherein the protective layer includes resin.

17. The method of claim 10, wherein the first portion includes a first sub-portion which overlaps the second portion and a second sub-portion which does not overlap the second portion, and
wherein the first sub-portion includes a support unit protruding in one direction.

18. The method of claim 17, wherein the support unit is spaced apart from the bending unit and has a shape surrounding the bending unit.
